(19) United States
(12) Patent Application Publication
(10) Pub. No.: US 2006/0022252 A1
(43) Pub. Date: Feb. 2, 2006

(54) Nonvolatile memory device and method of fabricating the same

(75) Inventors: Seok-Joo Doh, Suwon-si (KR); Jong-Pyo Kim, Seongnam-si (KR); Jong-Ho Lee, Suwon-si (KR); Ki-Chul Kim, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/193,231

(22) Filed: Jul. 29, 2005

(30) Foreign Application Priority Data
Jul. 30, 2004 (KR) 10-2004-0060338

(51) Int. Cl. H01L 29/76

(52) U.S. Cl. 257/314

(57) ABSTRACT

There are provided a nonvolatile memory device and a method of fabricating the same. A gate region of the nonvolatile memory device is formed as a stack structure including a tunnel oxide layer, a trapping layer, a blocking layer and a control gate electrode. The trapping layer is formed of a high-k dielectric having a higher dielectric constant than that of the tunnel oxide layer. When the trapping layer is formed of high-k dielectric, an EOT in a same thickness can be reduced, and excitation of electrons of the control gate electrode to the tunnel oxide layer due to a high potential barrier relative to the tunnel oxide layer is prevented so that program and erase voltages can be further reduced. As such, a problem that the tunnel oxide layer is damaged due to the conventional high program and erase voltages can be solved by reducing the program and erase voltages, and program and erase speeds of the transistor can be further improved.

### CROSS-REFERENCE TO RELATED APPLICATION

This application claims the benefit of Korean Patent Application No. 10-2004-0060338, filed Jul. 30, 2004, the contents of which are hereby incorporated herein by reference in their entirety.

### BACKGROUND OF THE INVENTION

1. Technical Field

The present invention relates to a nonvolatile memory device and a method of fabricating the same, and, more particularly, to a nonvolatile memory device having an improved gate structure for improving program and erase speeds, and a method of fabricating the same.

2. Discussion of Related Art

Generally, semiconductor memory devices used to store data are classified as volatile memory devices and nonvolatile memory devices. While the volatile memory device loses stored data when power supply is removed, the nonvolatile memory device retains stored data even though power supply is removed. Therefore, the nonvolatile memory device can be widely used for memory cards to store music or image data, or in mobile telephone systems in which power cannot be continuously supplied or the power supply may be intermittently interrupted. Various improved structures and operation methods for nonvolatile memory devices have been actively studied to increase operation speeds because nonvolatile memory devices are behind volatile memory devices in the aspect of operation speeds.

Generally, a cell transistor of the nonvolatile memory device employs a stack gate structure. The stack gate structure includes a tunnel oxide layer, a floating gate, an inter-gate dielectric, and a control gate electrode, which are sequentially stacked on a channel region of the cell transistor. The stack structure of the nonvolatile memory device causes a high step height difference relative to a cell array region and peripheral circuit regions, thereby resulting in difficulties in performing subsequent processing steps. Furthermore, since a process of patterning the floating gate is complicated, and the surface area of the floating gate is difficult to increase, a coupling ratio of the cell transistor in the nonvolatile memory device, which influences program and erase characteristics of the cell transistor, cannot be sufficiently ensured. Since the program and erase characteristics of the nonvolatile memory device are very important factors in evaluating the quality of the device, the increase of the surface area of the floating gate is a major concern. However, the process of increasing the surface area of the floating gate has many difficulties as the integration degree of the nonvolatile memory device is gradually increased.

In response, a SONOS gate structure employing dielectrics having a high trap concentration for a trapping layer in order to solve the problem in which the program and erase characteristics are degraded due to the limitation to increasing the surface area of the floating gate has been proposed.

FIG. 1 is a sectional view illustrating a conventional SONOS memory device.

Referring to FIG. 1, a diffusion region 12 functioning as source and drain regions is formed in a semiconductor substrate 10, and a gate is formed on a channel region defined by the diffusion region 12. The gate includes a tunnel oxide layer 14, a trapping layer 16, a blocking layer 18, and a control gate electrode 20, which are sequentially stacked.

The semiconductor substrate 10 is a p-type silicon substrate, and the control gate electrode 20 is composed of p-type polysilicon. The tunnel oxide layer 14 and the blocking layer 18 are formed of silicon oxide layers, and the trapping layer 16 is formed of a silicon nitride (SiN) layer, an insulating layer having a high trap concentration and a high electron affinity (that is, low band gap energy) in comparison with the tunnel oxide layer 14 and the blocking layer 18, thereby completing the formation of the SONOS gate structure.

FIG. 2 is an energy band diagram in the thermal equilibrium state of the conventional SONOS memory device, taken along a line of A-A′ of FIG. 1.

Referring to FIG. 2, a Fermi level is uniform throughout the whole structure, the energy band of the p-type semiconductor substrate 10 and the n-type control gate electrode 20 by the work function difference is curved in the thermal equilibrium state as shown in the drawing. The control gate electrode 20 has about 3 eV of work function (Φsi), which may be varied in accordance with a doping concentration of n-type impurities.

FIG. 3 is an energy band diagram in the thermal equilibrium state of the conventional SONOS memory device of FIG. 2 in an erase mode.

Referring to FIG. 3, a higher voltage is applied to the semiconductor substrate 10 than to the control gate electrode of the SONOS memory device in an erase mode. For example, the control gate electrode 20 is grounded, and +15 V of voltage is applied to the semiconductor substrate 10. Alternatively, the semiconductor substrate 10 may be grounded and −15 V of voltage may be applied to the control gate electrode 20. As a result, as shown in FIG. 3, the thermal equilibrium state of the system is broken by externally applied voltage, and a Fermi level (Efn) of the control gate electrode 20 is increased higher than a Fermi level (Efp) of the semiconductor substrate. Also, the shapes of conduction bands of the tunnel oxide layer 14, the trapping layer 16, and the blocking layer 18 are changed.

In the erase mode, the electrons stored inside the trapping layer 16 are discharged to the semiconductor substrate 10 by tunneling (Jt) through the tunnel oxide layer 14, and holes are injected from the semiconductor substrate 10 to the trapping layer 16 by tunneling through the tunnel oxide layer 14.

In the erase mode of the nonvolatile memory device, a threshold voltage preferably has a negative (−) value. However, since the polysilicon has a low work function, and when electrons are injected from the control gate electrode 20 to the trapping layer 16 by tunneling (Jb) through the blocking layer 18, a threshold voltage of the transistor converges into a constant level. Therefore, since it takes a long time to decrease the threshold voltage of the transistor, the time for data erasing is lengthened.

As described above, while the nonvolatile memory device has an advantage of storing data without power supply, it has a disadvantage of a low operation speed because the data program and erase are conducted by using a threshold voltage of the transistor, which is changed when electrons or holes are injected into the trapping layer, and injected electrons or holes are discharged out of the trapping layer. Therefore, there have been proposed various improved structures of the SONOS memory device in order to decrease a threshold voltage of the transistor below a predetermined level during an erase mode for removing electrons from the trapping layer.

FIG. 4 is a sectional view illustrating another conventional SONOS memory device.

Referring to FIG. 4, a diffusion region 12 functioning as source and drain regions is formed in a semiconductor substrate 10, and a gate is formed on a channel region defined by the diffusion region 12. The gate includes a tunnel oxide layer 14, a trapping layer 16, a blocking layer 22, and a control gate electrode 24, which are sequentially stacked.

The semiconductor substrate 10 uses a p-type silicon substrate, the tunnel oxide 14 is formed of a silicon oxide layer, and the trapping layer 16 is composed of silicon nitride (SiN) having a high trap concentration.

In order to improve the characteristics of the SONOS memory device shown in FIG. 1, the control gate electrode 24 is composed of metal having a higher work function (em) than that of polysilicon. Specifically, the control gate electrode 24 may be composed of metal having 4 eV of work function or more, and, for example, may be composed of titanium (Ti), titanium nitride (TiN), tantalum (Ta), tantalum nitride (TaN), tungsten (W), tungsten nitride (WN), hafnium (Hf), niobium (Nb), molybdenum (Mo), ruthenium dioxide (RuO₂), molybdenum nitride (MO₂N), iridium (Ir), platinum (Pt), cobalt (Co), chrome (Cr), ruthenium monoxide (RuO), titanium aluminide (Ti₃Al), titanium aluminum nitride (Ti₂AlN), palladium (Pd), tungsten nitride (WNₓ), tungsten silicide (WSi), or nickel silicide (NiSi), or may be composed of mixture including two or more of these metals. The blocking layer 22 is composed of a material having a higher dielectric constant than that of the tunnel oxide layer 14. The dielectric material used to form the blocking layer 22 may use oxide of the group III or VB elements of the Mendeleev Periodic Table, oxide of the group III or VB elements of the Mendeleev Periodic Table doped with the group IV elements, for example, zirconium (Zr), silicon (Si), titanium (Ti), or hafnium (Hf), or high-k dielectrics_such as hafnium oxide (HfO₂) layer, hafnium aluminate (Hf₁₋ₓAlₓO_{y}), hafnium silicate (HfₓSi₁₋ₓO₂), or the like.

When the control gate electrode 24 is composed of metal having a high work function, a leakage current is suppressed. A first reason for the leakage current suppression is that the number of electrons tunneling the blocking layer 22 is reduced because an electron barrier is increased during an erase mode, and a second reason is that if the control gate electrode 24 is composed of polysilicon, an interfacial layer is formed on the interface with the metal oxide layer of the blocking layer by a subsequent annealing process, thereby to cause a leakage current, but if the control gate electrode 24 is composed of metal, leakage current characteristics at the interface is improved by the thermal stability. Therefore, when the control gate electrode is composed of metal, the number of the electrons tunneling the blocking layer 18 and being injected into the trapping layer 16 can be reduced, thereby alleviating the problem that it took a long time to reduce the threshold voltage of the transistor.

If the blocking layer 22 is formed of a high-k dielectric having a high dielectric constant, a potential difference between the control gate electrode 24 and the semiconductor substrate 10 couples to the tunnel oxide_layer 14 more highly than to the blocking layer 22. Therefore, since the charge amount tunneling the tunnel oxide layer 14 can be significantly increased with respect to the charge amount tunneling the blocking layer 22 during the program and erase modes, the time to program and erase the transistor can be shortened.

As such, when the control gate electrode 24 is composed of metal and the blocking layer 22 is composed of high-k dielectrics, the energy band diagram in the thermal equilibrium state of the SONOS memory device is illustrated in FIG. 5.

FIG. 5 is an energy band diagram in the thermal equilibrium state of the conventional SONOS memory device of FIG. 4 taken along a line of B-B′. In the case that the control gate electrode 24 is composed of metal, a higher potential is required to inject electrons from the control gate electrode to the blocking insulating layer. Therefore, it alleviates the problem of the SONOS memory device shown in FIG. 1, in which it takes a long time to reduce the threshold voltage of the transistor when the electrons of the control gate electrode 24 are injected into the trapping layer 16 through easy tunneling of the blocking layer. Further, when the blocking layer 22 is composed of high-k dielectrics having a high dielectric constant, a potential difference between the control gate electrode 24 and the semiconductor substrate 10 couples to the tunnel oxide layer more highly than_to the blocking layer. As a result, since the charge amount tunneling the tunnel oxide layer during the data program and erase can be increased more than the charge amount tunneling the blocking layer, the time required to program and erase data can be shortened.

FIG. 6 illustrates an energy band diagram during an erase mode of the SONOS memory device of FIG. 4.

Referring to FIG. 6, if a high positive voltage is applied to the semiconductor substrate, or a high negative voltage is applied to the control gate electrode, the thermal equilibrium of the structure is broken. Thus, the electrons in the trapping layer tunnel the tunnel oxide layer and are discharged to the semiconductor substrate. Conventionally, the erase time of the transistor during the erase mode was long due to the electrons (leakage current) injected from the control gate electrode to the trapping layer by tunneling through the blocking layer, but when the control gate electrode 24 is composed of metal and the blocking layer 22 is composed of high-k dielectrics, a possibility that electrons tunnel the blocking layer 22 is decreased due to the high potential barrier between the control gate electrode 24 and the blocking layer 22. As a result, the threshold voltage during the erase mode can be decreased, and the time for data erase in the transistor can be shortened.

However, the SONOS structure shown in FIG. 4 generates a high potential barrier between the control gate electrode and the blocking layer so as to decrease a possibility that electrons tunnel the blocking insulating layer, but cannot improve program and erase speeds of the transistor due to the leakage current of the tunnel oxide layer. In order to improve the program and erase speeds, program and erase voltages must be increased. However, the increase of program and erase voltages may cause problems, such as degradation of the tunnel oxide layer, and malfunctions of endurance and data retention.

Therefore, it is required to develop a SONOS gate structure for increasing program and erase speeds of the transistor, that is, an improved SONOS gate structure, in which program time and erase time are shortened, without the need to apply program and erase voltages high enough to degrade the tunnel oxide layer.

### SUMMARY OF THE INVENTION

Therefore, the present invention provides a nonvolatile memory device for improving program and erase speeds while decreasing program and erase voltages, and a method of fabricating the same.

The present invention also provides a nonvolatile memory device for improving program and erase speeds while preventing degradation of a tunnel oxide layer, and a method of fabricating the same.

The present invention also provides a nonvolatile memory device for improving program and erase speeds while decreasing a leakage current of a tunnel oxide layer, and a method of fabricating the same.

According to a first aspect, the invention provides a nonvolatile memory device comprising a tunnel oxide layer formed on a channel region of a semiconductor substrate. A trapping layer is formed on the tunnel oxide layer, the trapping layer comprising a high-k dielectric having a higher dielectric constant than that of the tunnel oxide layer. A blocking layer is formed on the trapping layer, the blocking layer comprising a high-k dielectric having a higher dielectric constant than that of the tunnel oxide layer. A control gate electrode is formed on the blocking layer.

In one embodiment, the tunnel oxide layer comprises at least one of SiN and SION.

In one embodiment, the control gate electrode is formed of a material layer comprising one of polysilicon, a metal material having a work function of 4 eV or more, and a stack structure including polysilicon and a metal material having a work function of 4 eV or more.

In one embodiment, the metal material is one of: (a) a metal selected from the group consisting of titanium (Ti), titanium nitride (TiN), tantalum nitride (TaN), tantalum (Ta), tungsten (W), tungsten nitride (WN), hafnium (Hf), niobium (Nb), molybdenum (Mo), ruthenium dioxide (RuO₂), molybdenum nitride (MO₂N), iridium (Ir), platinum (Pt), cobalt (Co), chrome (Cr), ruthenium monoxide (RuO), titanium aluminide (Ti₃Al), titanium aluminum nitride (Ti₂AlN), palladium (Pd), tungsten nitride (WNₓ), tungsten silicide (WSi), and nickel silicide (NiSi), (b) a stack structure including at least two selected from the group listed in (a) above.

In one embodiment, the trapping layer is a high-k dielectric. In one embodiment, the high-k dielectric is a metal oxide layer. In one embodiment, the metal oxide layer comprises one of: (a) a material selected from the group consisting of HfO, HfON, HfAlO, HfAlON, AlO, AlON, HfSiO, HfSiON, hafnium oxide (HfO₂), hafnium aluminate (Hf₁₋ₓAlₓO_{y}), and hafnium silicate (HfSi₁₋ₓO₂); (b) an oxide of the group III or VB elements of the Mendeleev Periodic Table doped with the group IV elements; and (c) one of a stack structure and a compound of metal oxide layers. In one embodiment, the group III element is a lanthanide group element. In one embodiment, the lanthanide group element includes La₂O₃ or Dy₂O₃. In one embodiment, the group IV element is one of zirconium (Zr), silicon (Si), titanium (Ti) and hafnium (Hf).

The trapping layer can be formed by deposition using one of an ALD method and a CVD method.

The blocking layer can be a high-k dielectric. The high-k dielectric can be a metal oxide layer.

In one embodiment, the metal oxide layer comprises one of: (a) a material selected from the group consisting of HfO, HfON, HfAlO, HfAlON, AlO, AlON, HfSiO, HfSiON, hafnium oxide (HfO₂), hafnium aluminate (Hf₁₋ₓAlₓO_{y}), and hafnium silicate (HfSi₁₋ₓO₂); (b) an oxide of the group III or VB elements of the Mendeleev Periodic Table doped with the group IV elements; and (c) one of a stack structure and a compound of metal oxide layers. The group III element can be a lanthanide group element. The lanthanide group element can include one of La₂O₃ and Dy₂O₃. The group IV element can be one of zirconium (Zr), silicon (Si), titanium (Ti) and hafnium (Hf).

In one embodiment, the blocking layer is formed by deposition using an ALD method.

In one embodiment, the gate structure of the nonvolatile memory device is a structure in which a portion of the control gate electrode overlaps the trapping layer by etching the trapping layer before forming the blocking layer.

According to another aspect, the invention is directed to a method of fabricating a nonvolatile memory device. According to the method, an insulating layer is formed on a semiconductor substrate. A first high-k dielectric is formed on the insulating layer. A second high-k dielectric is formed on the first high-k dielectric. A conductive layer is formed on the second high-k dielectric. The insulating layer, the first high-k dielectric, the second high-k dielectric, and the conductive layer are etched, thereby forming a gate region including a tunnel oxide layer, a trapping layer, a blocking layer, and a control gate electrode on a channel region of the semiconductor substrate.

In one embodiment, the tunnel oxide layer includes one of SiN and SiON. In one embodiment, the control gate electrode is formed of a material layer comprising one of polysilicon, a metal material having a work function of 4 eV or more, and a stack structure including polysilicon and a metal material having a work function of 4 eV or more. In one embodiment, the metal material is one of: (a) a metal selected from the group consisting of titanium (Ti), titanium nitride (TiN), tantalum nitride (TaN), tantalum (Ta), tungsten (W), tungsten nitride (WN), hafnium (Hf), niobium (Nb), molybdenum (Mo), ruthenium dioxide (RuO₂), molybdenum nitride (MO₂N), iridium (Ir), platinum (Pt), cobalt (Co), chrome (Cr), ruthenium monoxide (RuO), titanium aluminide (Ti₃Al), titanium aluminum nitride (Ti₂AlN), palladium (Pd), tungsten nitride (WNₓ), tungsten silicide (WSi), and nickel silicide (NiSi), (b) a stack structure including at least two selected from the group listed in (a) above.

In one embodiment, the trapping layer comprises a high-k dielectric. In one embodiment, the high-k dielectric comprises a metal oxide layer. In one embodiment, the metal oxide layer comprises one of: (a) a material selected from the group consisting of HfO, HfON, HfAlO, HfAlON, AlO, AlON, HfSiO, HfSiON, hafnium oxide (HfO₂), hafnium aluminate (Hf₁₋ₓAlₓO_{y}), and hafnium silicate (HfSi₁₋ₓO₂); (b) an oxide of the group III or VB elements of the Mendeleev Periodic Table doped with the group IV elements; and (c) one of a stack structure and a compound of metal oxide layers. In one embodiment, the group III element is a lanthanide group element. In one embodiment, the lanthanide group element includes one of La₂O₃ and Dy₂O₃. In one embodiment, the group IV element is one of zirconium (Zr), silicon (Si), titanium (Ti) and hafnium (Hf).

In one embodiment, the trapping layer is formed by deposition using one of an ALD method and a CVD method.

In one embodiment, the blocking layer comprises a high-k dielectric. In one embodiment, the high-k dielectric comprises a metal oxide layer. In one embodiment, the metal oxide layer comprises one of: (a) a material selected from the group consisting of HfO, HfON, HfAlO, HfAlON, AlO, AlON, HfSiO, HfSiON, hafnium oxide (HfO₂), hafnium aluminate (Hf₁₋ₓAlₓO_{y}), and hafnium silicate (HfSi₁₋ₓO₂); (b) an oxide of the group III or VB elements of the Mendeleev Periodic Table doped with the group IV elements; and (c) one of a stack structure and a compound of metal oxide layers. In one embodiment, the group III element is a lanthanide group element. In one embodiment, the lanthanide group element includes one of La₂O₃ and Dy₂O₃.

In one embodiment, the group IV element is one of zirconium (Zr), silicon (Si), titanium (Ti) and hafnium (Hf).

In one embodiment, the blocking layer is formed by deposition using an ALD method. In one embodiment, after forming the blocking layer, a PDA process is performed at a temperature of 650 to 1050° C. in an atmosphere comprising at least one of N₂, NO, N₂O, O₂, and NH₃.

In one embodiment, before forming the second high-k dielectric, further comprising performing an etch process on the first high-k dielectric so that a portion of the control gate electrode to be formed during a subsequent process overlaps the trapping layer.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a sectional view illustrating a conventional SONOS memory device.

FIG. 2 is an energy band diagram in the thermal equilibrium state of the conventional SONOS memory device, taken along a line of A-A′ of FIG. 1.

FIG. 3 is an energy band diagram in the thermal equilibrium state of the conventional SONOS memory device of FIG. 2 in an erase mode.

FIG. 4 is a sectional view illustrating another conventional SONOS memory device.

FIG. 5 is an energy band diagram in the thermal equilibrium state of the conventional SONOS memory device of FIG. 4, taken along a line of B-B′ of FIG. 4.

FIG. 6 is an energy band diagram of the conventional SONOS memory device of FIG. 4 in an erase mode.

FIGS. 7A through 7C are sectional views illustrating a method of fabricating a nonvolatile memory device according to an embodiment of the present invention.

FIG. 8 is a graph illustrating C-V hysteresis characteristic of a nonvolatile memory device according to an embodiment of the present invention.

FIG. 9 is a graph illustrating C-V hysteresis characteristic of a nonvolatile memory device in the case that a blocking layer is composed of SiO₂ according to an embodiment of the present invention.

FIG. 10 is a graph illustrating C-V curve shift characteristic in the case that +10 V of program voltage is applied to a nonvolatile memory device according to an embodiment of the present invention.

FIG. 11 is a graph illustrating C-V curve shift characteristic in the case that +12 V of program voltage is applied to a nonvolatile memory device according to an embodiment of the present invention.

FIG. 12 is a graph illustrating C-V curve shift characteristic in the case that −10 V of erase voltage is applied to a nonvolatile memory device according to an embodiment of the present invention.

FIG. 13 is a graph illustrating C-V curve shift characteristic in the case that −12 V of erase voltage is applied to a nonvolatile memory device according to an embodiment of the present invention.

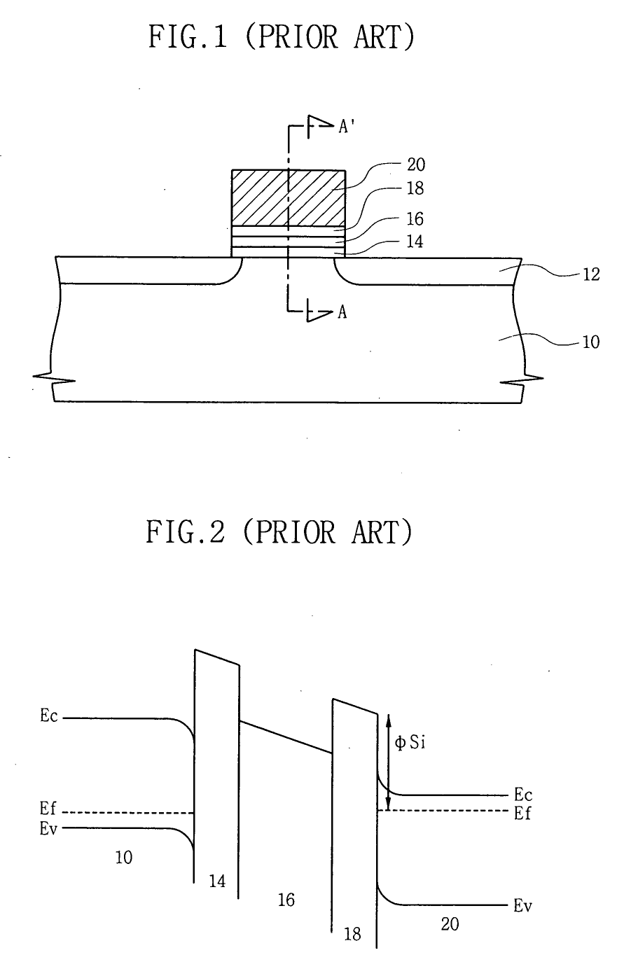

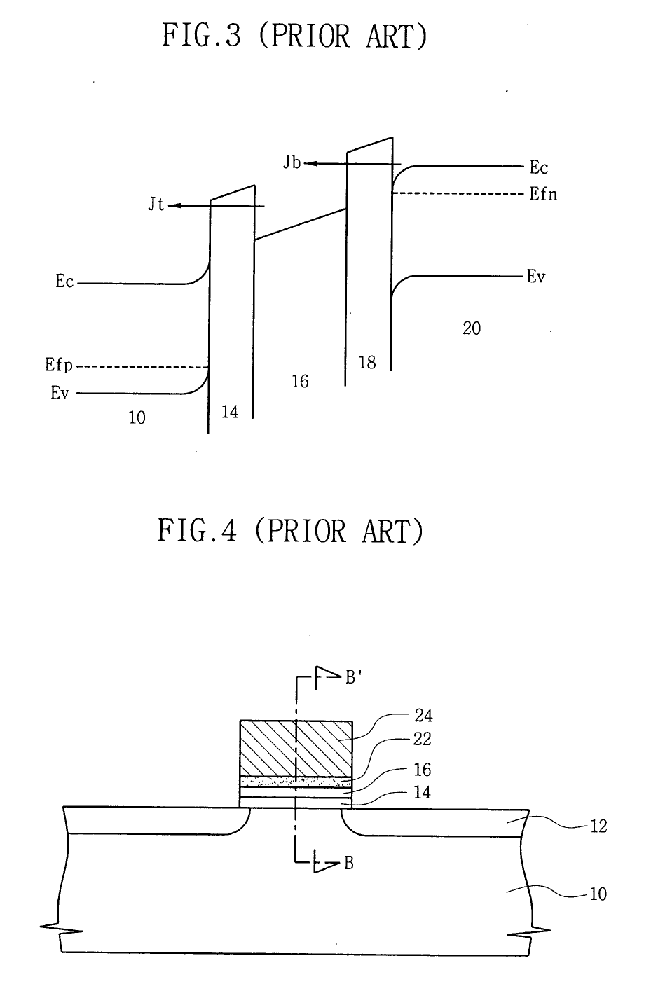

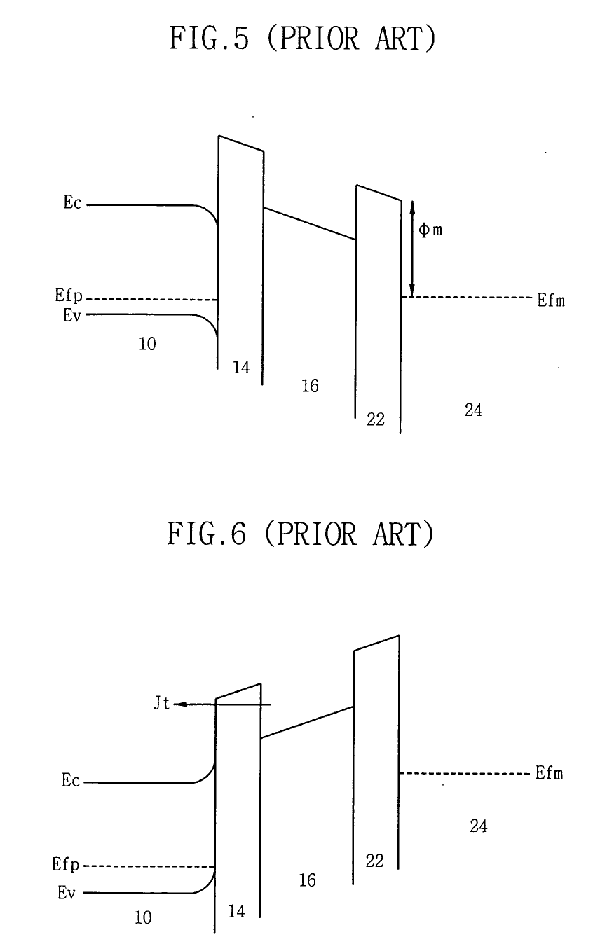

### DETAILED DESCRIPTION OF THE INVENTION

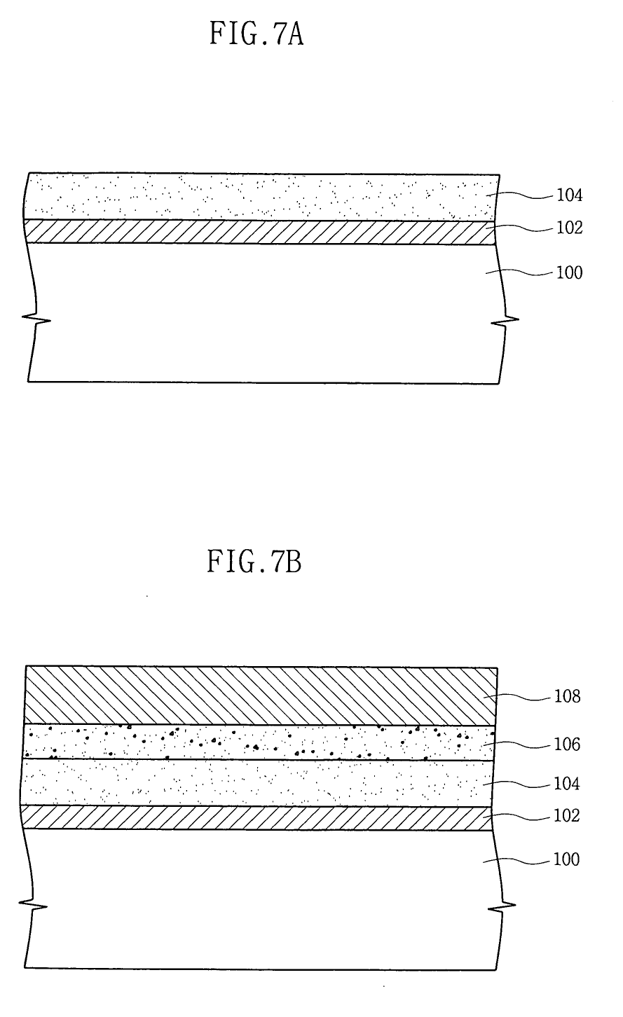

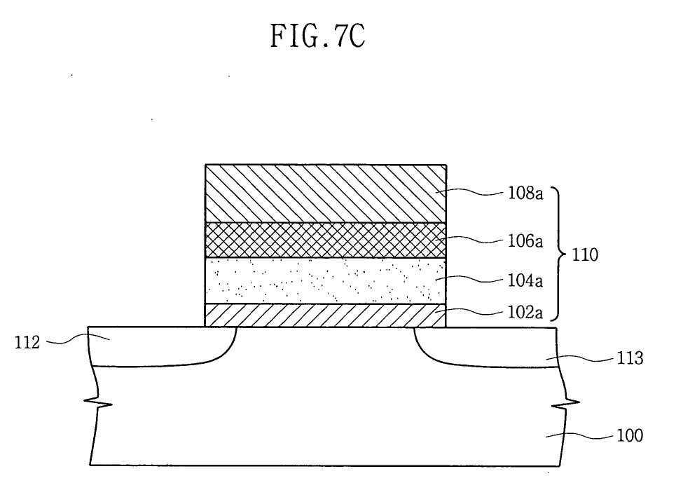

FIGS. 7A through 7B are sectional views illustrating a method of fabricating a nonvolatile memory device according to an embodiment of the present invention.

Referring to FIG. 7A, an insulating layer 102 is formed on a p-type semiconductor substrate 100, and the insulating layer 102 will function as a tunnel oxide layer for electron tunneling. The insulating layer 102 is composed of SiO or SION, and the material may be deposited using a chemical vapor deposition (CVD) method.

Then, a first high-k dielectric 104 is deposited on the insulating layer 102 to form a trapping layer functioning as a charge storage layer. The formation of the trapping layer using the high-k dielectric 104 is one of the features of the present invention, and the first high-k dielectric 104 is preferably deposited using an atomic layer deposition (ALD) or CVD method. The first high-k dielectric 104 is formed of a metal oxide layer, and may be composed of a material selected from HfO, HfON, HfAlO, HfAlON, AlO, AlON, HfSiO or HfSiON, or may be composed of oxide of the group III or VB elements of the Periodic Table, doped with the group IV elements, for example, zirconium (Zr), silicon (Si), titanium (Ti), or hafnium (Hf). Alternatively, the first high-k dielectric 104 may be formed of a stack structure of the metal oxide layers, or a composite structure, such as hafnium oxide (HfO₂) layer, hafnium aluminate (Hf₁₋ₓAlₓO_{y}), or hafnium silicate (HfSi₁₋ₓO₂). The group III elements used to form the high-k dielectric 104 may use lanthanide group of elements, for example, La₂O₃ or Dy₂O₃.

Referring to FIG. 7B, a second high-k dielectric 106 is deposited on the semiconductor substrate 100 having the insulating layer 102 and the first high-k dielectric 104 formed thereon to form a blocking layer. The second high-k dielectric 106 is preferably deposited using an ALD method. Like the first high-k dielectric 104, the second high-k dielectric 106 may be formed of a metal oxide layer, such as HfO, HfON, HfAlO, HfAlON, AlO, AlON, HfSiO or HfSiON, or may be composed of oxide of the group III or VB elements of the Periodic Table, doped with the group IV elements, for example, zirconium (Zr), silicon (Si), titanium (Ti), or hafnium (Hf). Alternatively, the second high-k dielectric 106 may be formed of a stack structure of the metal oxide layers, or a composite structure, such as hafnium oxide (HfO₂) layer, hafnium aluminate (Hf₁₋ₓAlₓO_{y}), or hafnium silicate (HfSi₁₋ₓO₂). The group III elements used to form the second high-k dielectric 106 may use lanthanide group of elements, for example, La₂O₃ or Dy₂O₃.

Then, after the second high-k dielectric 106 is deposited, a post deposition annealing (PDA) process is performed to increase a concentration of the dielectrics. The PDA is preferably performed at a temperature of 650 to 1050° C., and in the atmosphere of any gas selected from N₂, NO, N₂O, O₂, and NH₃ or a mixture thereof.

Further, by patterning the first high-k dielectric 104 using a photolithography process or a dry etch process before the second high-k dielectric 106 is formed, a gate structure can be achieved such that the trapping layer partially overlaps a control gate electrode to be formed in a subsequent process.

Referring to FIG. 7C, a conductive layer 108 is formed on the semiconductor substrate 100 having the second high-k dielectric 106 deposited thereon, so as to form a control gate electrode. In one embodiment, the conductive layer 108 is formed of polysilicon or metal material having a work function of 4 eV or more, or a stack structure including polysilicon and metal material having a work function of 4 eV or more. When the control gate electrode is formed of the metal material having a work function of 4 eV or more, the metal material may use any one among Ti, TiN, TaN, Ta, W, WN, Hf, Nb, Mo, RuO₂, Mo₂N, Ir, Pt, Co, Cr, RuO, Ti₃Al, Ti₂AlN, Pd, WNₓ, WSi, and NiSi, or the control gate electrode may be composed of a stack structure including at least two or more among the metal materials.

Then, a typical CMOS process is performed on the semiconductor substrate having the electrode material layer formed thereon to form the control gate electrode, thereby forming a transistor. First, photoresist (not shown) is deposited on the semiconductor substrate 100 having the conductive layer 108 formed thereon, and the conductive layer 108, the second high-k dielectric 106, the first high-k dielectric 104, and the insulating layer 102 are sequentially etched along a mask pattern (not shown). As a result, a gate region 110 is formed with a stack structure including a tunnel oxide layer 102a, a trapping layer 104a, a blocking layer 106a, and a control gate electrode 108a. Then, using the gate region 110 as a self-aligned mask pattern, n-type impurities are implanted on the p-type semiconductor substrate 100, thereby forming a source region 112 and a drain region 113.

As described above, when the trapping layer of the gate region 110 is formed of high-k dielectrics according to the present invention, program and erase characteristics of the nonvolatile memory device can be improved. This improvement is realized because, In prior devices, the trapping layer of the conventional gate region has been composed of SiN, and the SiN has 1.03 eV of potential barrier against the tunnel oxide layer. Because of that, when the trapping layer of the gate region is composed of SiN, electrons can be easily activated and pass over into the tunnel oxide layer, thereby causing a leakage current in the tunnel oxide layer. Therefore, in order to solve the problem according to the present invention, high-k dielectric material having a 1.65 eV of potential barrier being higher than that of SiN is employed to the trapping layer of the gate region 110. Since the potential barrier of the high-k dielectric is high, that is, 1.65 eV, in comparison with the potential barrier of SiN, 1.03 eV, the number of electrons activated and penetrating into the tunnel oxide layer can be significantly decreased. Therefore, since the number of electrons activated and penetrating into the tunnel oxide layer is decreased, the generation of leakage current of the tunnel oxide layer is also decreased.

Further, since SiN has a low dielectric constant, there is a limitation to reducing a thickness of SiN when forming the trapping layer using SiN. Therefore, it has been required to employ a dielectric being thicker than a SiN layer and improving the performance of the element. The performance of the dielectrics can be evaluated by equivalent oxide thickness (EOT). According to the present invention, a new high-k dielectric is employed for a dielectric layer while replacing the SiN and providing high performance. Therefore, while the EOT can be reduced, and a voltage applied during program and erase modes of a transistor can be lowered, program and erase speeds can be further improved.

The improvement in transistor characteristics when employing high-k dielectrics for the trapping layer of the gate region in the nonvolatile memory device according to the present invention will be described using exemplary simulation results as follows.

First, the tunnel oxide layer 102a is formed by depositing SiON with a thickness of 28′ in the process for simulation. The trapping layer 104a may be formed of 100′ of hafnium oxide layer (HfO₂), or 100′ of HfO₂-Al₂O₃ laminate, which is formed by alternately stacking 20′ of HfO₂, and 10′ of Al₂O₃, by deposition. Alternatively, the trapping layer 104a may be formed of 100′ of HfO₂—Al₂O₃ aluminate, which is formed as an alloy of HfO₂ and Al₂O₃. The blocking layer 106a is formed by depositing Al₂O₃ with a thickness of 100′. The high-k dielectrics of the trapping layer 104a and the blocking layer 106a are deposited using an ALD method. The control gate electrode 108a is composed of polysilicon. An activation annealing process is performed at a temperature of 1000° C. for 10 seconds.

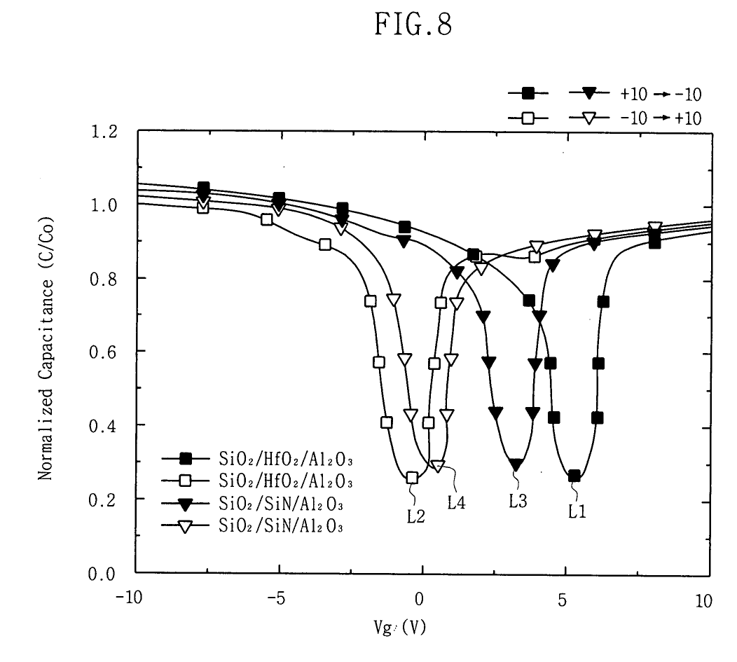

A C-V hysteresis curve of the nonvolatile memory device formed by the above process conditions is illustrated in FIG. 8.

Referring to FIG. 8, the x-axis represents voltages (−10˜10 V) applied to a control gate electrode, and the y-axis represents a normalized capacitance. L1 and L2 represent C-V hysteresis curves in the case that the tunnel oxide layer and the blocking layer are formed of SiO₂ (28′) and Al₂O₃ respectively, and the trapping layer is formed of HfO₂ (100′). L3 and L4 represent C-V hysteresis curves of a conventional typical SONOS structure in the case that the tunnel oxide layer and the blocking layer are formed of SiO₂ (28′) and Al₂O₃ (100′) respectively, and the trapping layer is formed of SiN (50′). More specifically, L1 and L3 represent change of Vfb (flatband voltage) when a voltage from +10 to −10 V is applied, and L2 and L4 represent change of Vfb (flatband voltage) when a voltage from −10 to +10 V is applied.

From the simulation result, the interval between L3 and L4 showing the change of Vfb when the trapping layer is formed of SiN is smaller than the interval between L1 and L2 showing the change of Vfb when the trapping layer is formed of high-k dielectrics such as HfO₂. Therefore, it is found from the ΔVfb that program and erase voltages of the transistor can be reduced and an operation speed can be improved when the blocking layer is formed of high-k dielectrics such as Al₂O₃.

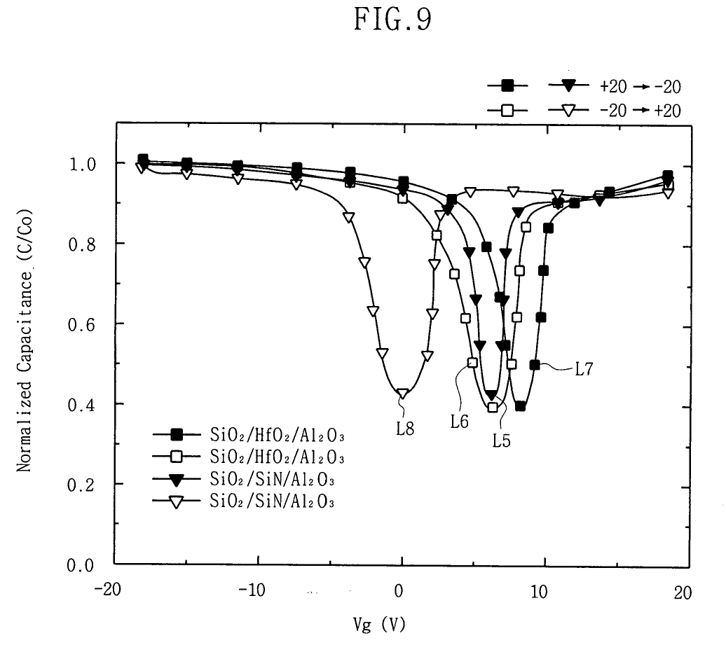

FIG. 9 is a graph illustrating the comparison with the simulation result of FIG. 8, and represents C-V hysteresis curves in the case that the trapping layer is formed of SiO₂ (100′) instead of Al₂O₃ of FIG. 8.

Referring to FIG. 9, the x-axis represents voltages (−20˜+20 V) applied to a control gate electrode, and the y-axis represents a normalized capacitance. L5 and L6 represent C-V hysteresis curves in the case that the tunnel oxide layer and the blocking layer are formed of SiO₂ (28′) and SiO₂ (100′) respectively, and the trapping layer is formed of HfO₂ (100′). L7 and L8 represent C-V hysteresis curves in the case that the tunnel oxide layer and the blocking layer are formed of SiO₂ (28′) and SiO₂ (100′) respectively, and the trapping layer is formed of SiN (50′). More specifically, L5 and L7 represent change of Vfb (flatband voltage) when a voltage from +20 to −20 V is applied, and L6 and L8 represent change of Vfb (flatband voltage) when a voltage from −20 to +20 V is applied.

From the simulation result, the interval between L7 and L8 showing the change of Vfb when the trapping layer is formed of SiN is greater than the interval between L5 and L6 showing the change of Vfb when the trapping layer is formed of high-k dielectrics such as HfO₂. Therefore, it is found that there is no gain value of ΔVfb in the case that the blocking layer is formed of SiO₂ even though the trapping layer is formed of high-k dielectrics such as HfO₂. The reason is that SiO₂ is normally deposited at a high temperature of 800° C. or higher in the atmosphere containing O₂, trap sites inside the high-k dielectrics are cured under the high temperature thermal annealing process condition in the oxygen atmosphere as above. Therefore, it is preferable to form the blocking layer using a material layer being deposited through the low temperature ALD process in order to form the trapping layer of high-k dielectrics.

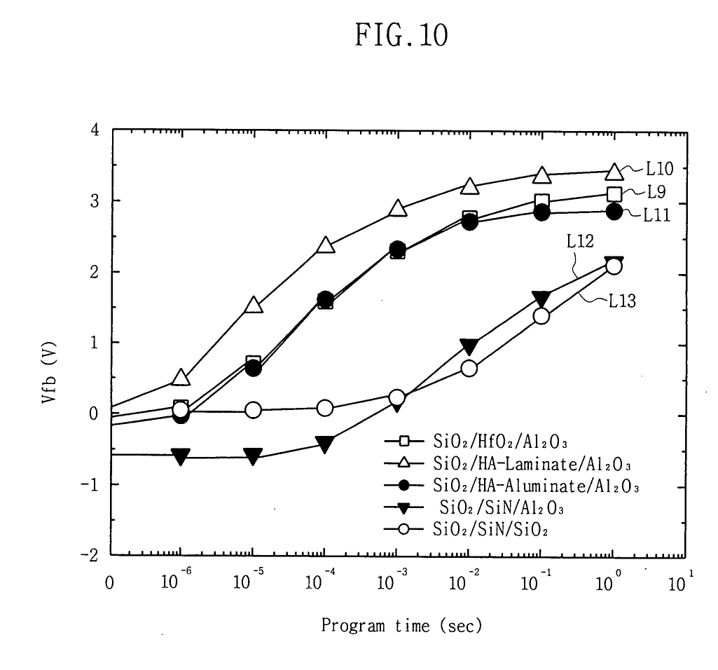

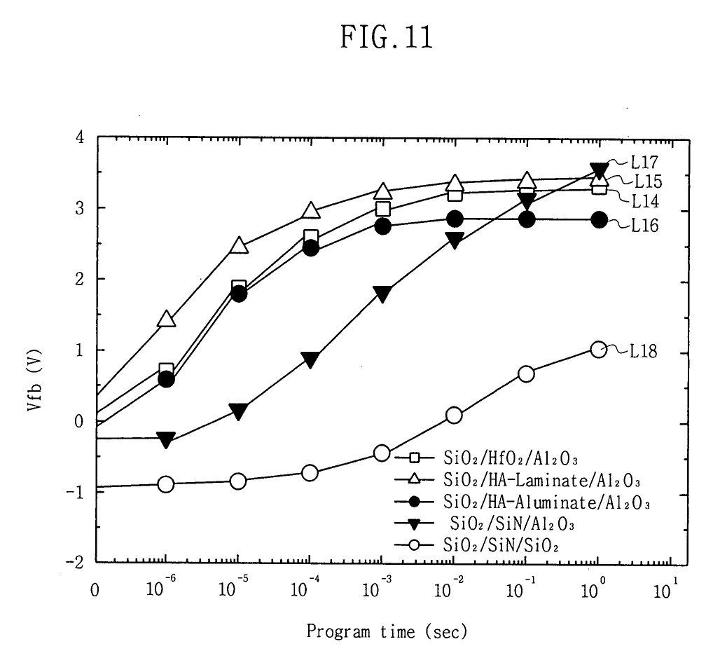

FIGS. 10 and 11 represent shifts of C-V curves illustrating ΔVfb versus program time of the nonvolatile memory device according to an embodiment of the present invention and the conventional SONOS memory device. The x-axis represents a program time, and the y-axis represents a Vfb.

FIG. 10 illustrates shifts of C-V curves in accordance with program time when +10 V of program voltage is applied, and FIG. 11 illustrates shifts of C-V curves in accordance with program time when +12 V of program voltage is applied.

Referring to FIG. 10, L9, L10, L11, and L12 illustrate shifts of C-V curves in the case that the tunnel oxide layer and the blocking layer are formed of SiO₂ (28′) and Al₂O₃ (100) respectively, and the trapping layer is formed of HfO₂ (100′), HfO₂—Al₂O₃ laminate (100′), HfO₂—Al₂O₃ aluminate (100′), and SiN (50′). L13 illustrates a shift of C-V curve of the conventional SONOS structure (SiO₂ (18′)/SiN (50′)/SiO₂ (100′)).

Referring to FIG. 11, L14, L15, L16, and L17 illustrate shifts of C-V curves in the case that the tunnel oxide layer and the blocking layer are formed of SiO₂ (28′) and Al₂O₃ (100) respectively, and the trapping layer is formed of HfO₂ (100′), HfO₂—Al₂O₃ laminate (100′), HfO₂—Al₂O₃ aluminate (100′), and SiN (50′). L18 illustrates a shift of C-V curve of the conventional SONOS structure (SiO₂ (18′)/SiN (50′)/SiO₂ (100′))

From the simulation results shown in FIGS. 10 and 11, the cases in that the trapping layer is formed of HfO₂, HfO₂—Al₂O₃ laminate (HA laminate) or HfO₂—Al₂O₃ aluminate show a higher ΔVfb than that of the case in that the trapping layer is formed of SiN at a same program time. Therefore, in the case that the blocking layer is formed of high-k dielectrics according to the present invention, that the program voltage can be lowered under the same program time condition. This also means that the program time can be further shortened in the case that a same program voltage is applied.

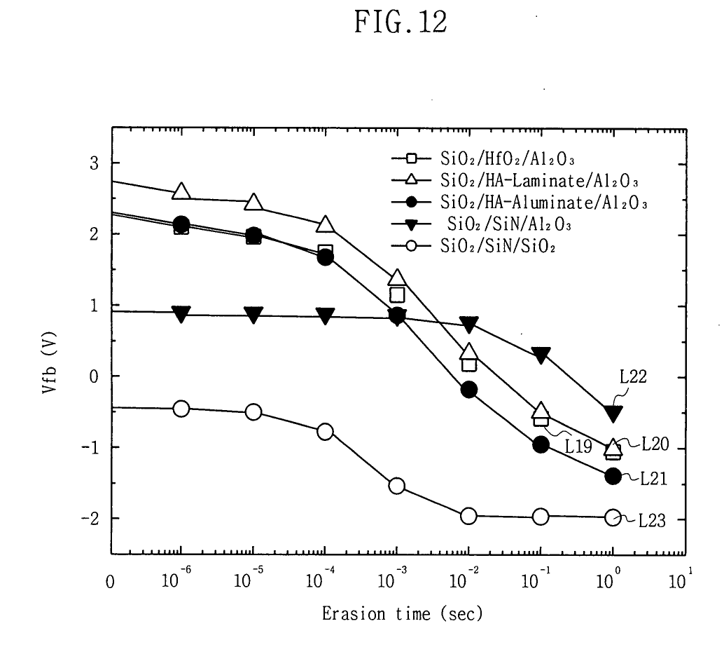

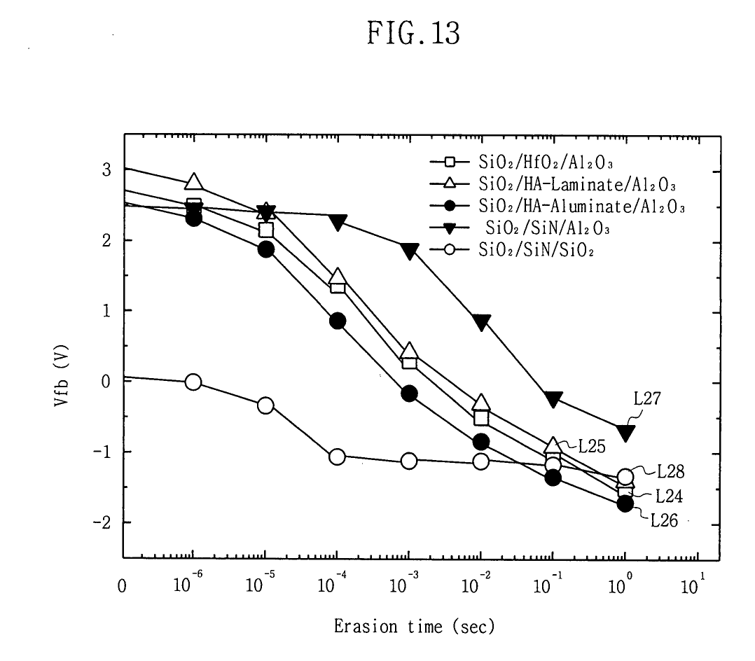

FIGS. 12 and 13 are graphs of C-V curve shifts illustrating ΔVfb versus erase time of the non-volatile memory device according to the embodiment of the present invention. The x-axis represents an erase time, and the y-axis represents Vfb.

FIG. 12 represents a C-V curve shift in accordance with an erase time in the case that −10V of erase voltage is applied, and FIG. 13 represents a C-V curve shift in accordance with an erase time in the case that −12V of erase voltage is applied.

First, referring to FIG. 12, L19, L20, L21, and L22 illustrate shifts of C-V curves in the case that the tunnel oxide layer and the blocking layer are formed of SiO₂ (28′) and Al₂O₃ (100′) respectively, and the trapping layer is formed of HfO₂ (100′), HfO₂—Al₂O₃ laminate (100′), HfO₂—Al₂O₃ aluminate (100′), and SiN (50′). L23 illustrates a shift of C-V curve of the conventional SONOS structure (SiO₂ (18′)/SiN (50′)/SiO₂ (100′)).

L24, L25, L26, and L27 of FIG. 13 illustrate shifts of C-V curves in the case that the tunnel oxide layer and the blocking layer are formed of SiO₂ (28′) and Al₂O₃ (100′) respectively, and the trapping layer is formed of HfO₂ (100′), HfO₂—Al₂O₃ laminate (100′), HfO₂—Al₂O₃ aluminate (100′), and SiN (50′). L28 illustrates a shift of C-V curve of the conventional SONOS structure (SiO₂ (18′)/SiN(50′)/SiO₂(100′)).

From the simulation results shown in FIGS. 12 and 13, the cases in that the trapping layer is formed of HfO₂, HfO₂—Al₂O₃ laminate (HA laminate) or HfO₂—Al₂O₃ aluminate show a higher ΔAVfb than that of the case in that the trapping layer is formed of SiN at a same erase time. Therefore, in the case that the blocking layer is formed of high-k dielectrics according to the present invention, it is acknowledged that the erase voltage can be lowered under the same erase time condition. This also means that the erase time can be further shortened in the case that a same erase voltage is applied.

As described above, when the trapping layer of the gate region in the nonvolatile memory device is formed of a high-k dielectrics not SiN of the conventional case, a leakage current of the tunnel oxide layer can be reduced, thereby improving program and erase characteristics of the transistor. Further, a high voltage was required during program and erase modes due to the leakage current of the tunnel oxide layer in the conventional case, resulting in degradation of the tunnel oxide layer. However, since the leakage current of the tunnel oxide layer can be reduced according to the present invention, the degradation problem of the tunnel oxide layer is solved.

FIGS. 8 to 13 illustrate simulation results in the case that the control gate electrode 108a employs polysilicon, and also in the case that the control gate electrode 108a employs metal material having work function of 4 eV or more, or a stack structure including polysilicon and metal material having work function of 4 eV or more, the transistor characteristics shown in FIGS. 8 to 13 can be achieved. Further, the present invention can be applied to the nonvolatile memory device having a structure in which the trapping layer partially overlaps the control gate electrode.

As described above, according to the present invention, when the gate region of the nonvolatile memory device is formed as a stack structure including the tunnel oxide layer, the trapping layer, the blocking layer, and the control gate electrode, the trapping layer is formed of high-k dielectrics having a higher dielectric constant than that of the tunnel oxide layer. As a result, since EOT in a same thickness can be reduced, and a high potential barrier relative to the tunnel oxide layer is formed, the problem of leakage current caused by the electrons of the control gate electrode excited to the tunnel oxide layer can be solved, and program and erase voltages of the transistor can be reduced. As such, since the program and erase voltages are reduced, a damage problem of the tunnel oxide layer caused by conventional high program and erase voltages can be solved, and program and erase speeds of the transistor can be further improved.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A nonvolatile memory device comprising:
a tunnel oxide layer formed on a channel region of a semiconductor substrate;
a trapping layer formed on the tunnel oxide layer, the trapping layer comprising a high-k dielectric having a higher dielectric constant than that of the tunnel oxide layer;
a blocking layer formed on the trapping layer, the blocking layer comprising a high-k dielectric having a higher dielectric constant than that of the tunnel oxide layer; and
a control gate electrode formed on the blocking layer.

2. The nonvolatile memory device according to claim 1, wherein the tunnel oxide layer comprises at least one of SiN and SiON.

3. The nonvolatile memory device according to claim 1, wherein the control gate electrode is formed of a material layer comprising one of polysilicon, a metal material having a work function of 4 eV or more, and a stack structure including polysilicon and a metal material having a work function of 4 eV or more.

4. The nonvolatile memory device according to claim 3, wherein the metal material is one of: (a) a metal selected from the group consisting of titanium (Ti), titanium nitride (TiN), tantalum nitride (TaN), tantalum (Ta), tungsten (W), tungsten nitride (WN), hafnium (Hf), niobium (Nb), molybdenum (Mo), ruthenium dioxide (RuO₂), molybdenum nitride (MO₂N), iridium (Ir), platinum (Pt), cobalt (Co), chrome (Cr), ruthenium monoxide (RuO), titanium aluminide (Ti₃Al), titanium aluminum nitride (Ti₂AlN), palladium (Pd), tungsten nitride (WNₓ), tungsten silicide (WSi), and nickel silicide (NiSi), (b) a stack structure including at least two selected from the group listed in (a) above.

5. The nonvolatile memory device according to claim 1, wherein the trapping layer is a high-k dielectric.

6. The nonvolatile memory device according to claim 5, wherein the high-k dielectric is a metal oxide layer.

7. The nonvolatile memory device according to claim 6, wherein the metal oxide layer comprises one of: (a) a material selected from the group consisting of HfO, HfON, HfAlO, HfAlON, AlO, AlON, HfSiO, HfSiON, hafnium oxide (HfO₂), hafnium aluminate (Hf₁₋ₓAlₓO_{y}), and hafnium silicate (HfSi₁₋ₓO₂); (b) an oxide of the group III or VB elements of the Mendeleev Periodic Table doped with the group IV elements; and (c) one of a stack structure and a compound of metal oxide layers.

8. The nonvolatile memory device according to claim 7, wherein the group III element is a lanthanide group element.

9. The nonvolatile memory device according to claim 8, wherein the lanthanide group element includes La₂O₃ or Dy₂O₃.

10. The nonvolatile memory device according to claim 7, wherein the group IV element is one of zirconium (Zr), silicon (Si), titanium (Ti) and hafnium (Hf).

11. The nonvolatile memory device according to claim 1, wherein the trapping layer is formed by deposition using one of an ALD method and a CVD method.

12. The nonvolatile memory device according to claim 1, wherein the blocking layer is a high-k dielectric.

13. The nonvolatile memory device according to claim 12, wherein the high-k dielectric is a metal oxide layer.

14. The nonvolatile memory device according to claim 6, wherein the metal oxide layer comprises one of: (a) a material selected from the group consisting of HfO, HfON, HfAlO, HfAlON, AlO, AlON, HfSiO, HfSiON, hafnium oxide (HfO₂), hafnium aluminate (Hf₁₋ₓAlₓO_{y}), and hafnium silicate (HfSi₁₋ₓO₂); (b) an oxide of the group III or VB elements of the Mendeleev Periodic Table doped with the group IV elements; and (c) one of a stack structure and a compound of metal oxide layers.

15. The nonvolatile memory device according to claim 14, wherein the group III element is a lanthanide group element.

16. The nonvolatile memory device according to claim 15, wherein the lanthanide group element includes one of La₂O₃ and Dy₂O₃.

17. The nonvolatile memory device according to claim 14, wherein the group IV element is one of zirconium (Zr), silicon (Si), titanium (Ti) and hafnium (Hf).

18. The nonvolatile memory device according to claim 1, wherein the blocking layer is formed by deposition using an ALD method.

19. The nonvolatile memory device according to claim 1, wherein the gate structure of the nonvolatile memory device is a structure in which a portion of the control gate electrode overlaps the trapping layer by etching the trapping layer before forming the blocking layer.

20. A method of fabricating a nonvolatile memory device comprising:
forming an insulating layer on a semiconductor substrate;
forming a first high-k dielectric on the insulating layer;
forming a second high-k dielectric on the first high-k dielectric;
forming a conductive layer on the second high-k dielectric; and
etching the insulating layer, the first high-k dielectric, the second high-k dielectric, and the conductive layer, thereby forming a gate region including a tunnel oxide layer, a trapping layer, a blocking layer, and a control gate electrode on a channel region of the semiconductor substrate.

21. The method according to claim 20, wherein the tunnel oxide layer comprises one of SiN and SiON.

22. The method according to claim 20, wherein the control gate electrode is formed of a material layer comprising one of polysilicon, a metal material having a work function of 4 eV or more, and a stack structure including polysilicon and a metal material having a work function of 4 eV or more.

23. The method according to claim 22, wherein the metal material is one of: (a) a metal selected from the group consisting of titanium (Ti), titanium nitride (TiN), tantalum nitride (TaN), tantalum (Ta), tungsten (W), tungsten nitride (WN), hafnium (Hf), niobium (Nb), molybdenum (Mo), ruthenium dioxide (RuO₂), molybdenum nitride (MO₂N), iridium (Ir), platinum (Pt), cobalt (Co), chrome (Cr), ruthenium monoxide (RuO), titanium aluminide (Ti₃Al), titanium aluminum nitride (Ti₂AlN), palladium (Pd), tungsten nitride (WNₓ), tungsten silicide (WSi), and nickel silicide (NiSi), (b) a stack structure including at least two selected from the group listed in (a) above.

24. The method according to claim 20, wherein the trapping layer comprises a high-k dielectric.

25. The method according to claim 24, wherein the high-k dielectric comprises a metal oxide layer.

26. The method according to claim 25, wherein the metal oxide layer comprises one of: (a) a material selected from the group consisting of HfO, HfON, HfAlO, HfAlON, AlO, AlON, HfSiO, HfSiON, hafnium oxide (HfO₂), hafnium aluminate (Hf₁₋ₓAlₓO_{y}), and hafnium silicate (HfSi₁₋ₓO₂); (b) an oxide of the group III or VB elements of the Mendeleev Periodic Table doped with the group IV elements; and (c) one of a stack structure and a compound of metal oxide layers.

27. The method according to claim 26, wherein the group III element is a lanthanide group element.

28. The method according to claim 27, wherein the lanthanide group element includes one of La₂O₃ and Dy₂O₃.

29. The method according to claim 26, wherein the group IV element is one of zirconium (Zr), silicon (Si), titanium (Ti) and hafnium (Hf).

30. The method according to claim 20, wherein the trapping layer is formed by deposition using one of an ALD method and a CVD method.

31. The method according to claim 20, wherein the blocking layer comprises a high-k dielectric.

32. The method according to claim 31, wherein the high-k dielectric comprises a metal oxide layer.

33. The method according to claim 32, wherein the metal oxide layer comprises one of: (a) a material selected from the group consisting of HfO, HfON, HfAlO, HfAlON, AlO, AlON, HfSiO, HfSiON, hafnium oxide (HfO₂), hafnium aluminate (Hf₁₋ₓAlₓO_{y}), and hafnium silicate (HfSi₁₋ₓO₂); (b) an oxide of the group III or VB elements of the Mendeleev Periodic Table doped with the group IV elements; and (c) one of a stack structure and a compound of metal oxide layers.

34. The method according to claim 33, wherein the group III element is a lanthanide group element.

35. The method according to claim 34, wherein the lanthanide group element includes one of La₂O₃ and Dy₂O₃.

36. The method according to claim 33, wherein the group IV element is one of zirconium (Zr), silicon (Si), titanium (Ti) and hafnium (Hf).

37. The method according to claim 31, wherein the blocking layer is formed by deposition using an ALD method.

38. The method according to claim 20, wherein, after forming the blocking layer, further comprising performing a PDA process at a temperature of 650 to 1050° C. in an atmosphere comprising at least one of N₂, NO, N₂O, O₂, and NH₃.

39. The method according to claim 20, wherein, before forming the second high-k dielectric, further comprising performing an etch process on the first high-k dielectric so that a portion of the control gate electrode to be formed during a subsequent process overlaps the trapping layer.
